(19) United States
(12) Patent Application Publication
(10) Pub. No.: US 2024/0063069 A1
(43) Pub. Date: Feb. 22, 2024

(54) ANGLED BAFFLES ON GLASS EDGE FOR CAVITATION PROTECTION

(71) Applicant: Intel Corporation, Santa Clara, CA (US)

(72) Inventors: Brandon C. MARIN, Gilbert, AZ (US); Rahul N. MANEPALLI, Chandler, AZ (US); Ravindranath V. MAHAJAN, Chandler, AZ (US); Srinivas V. PIETAMBARAM, Chandler, AZ (US); Jeremy D. ECTON, Gilbert, AZ (US); Gang DUAN, Chandler, AZ (US); Suddhasattwa NAD, Chandler, AZ (US)

(21) Appl. No.: 17/892,930

(22) Filed: Aug. 22, 2022

(51) Int. Cl. H01L 23/13; H01L 23/498; H01L 23/15

(52) U.S. Cl. CPC H01L 23/13; H01L 23/49816; H01L 23/49822; H01L 23/49833; H01L 23/49838; H01L 23/15; H01L 24/16

(57) ABSTRACT

Embodiments disclosed herein include package substrates with glass cores. In an embodiment, a core comprises a substrate with a first surface and a second surface opposite from the first surface. In an embodiment, the substrate comprises glass, In an embodiment, through glass vias (TGVs) pass through the substrate, and notches are formed into the first surface and the second surface of the substrate.

### TECHNICAL FIELD

Embodiments of the present disclosure relate to electronic packages, and more particularly to package substrates with glass cores that include exposed surfaces with angled baffles for cavitation protection.

### BACKGROUND

Recent trends in semiconductor packaging applications are to use glass cores for the package substrate. Glass cores enable improved stiffness and flatter surfaces. As such, routing in the buildup layers can have traces with finer line/space dimensions. Additionally, glass cores enable through glass vias (TGVs) that may provide improved electrical properties compared to traditional plated through holes that are formed through organic core substrates.

However, the use of a glass core negatively impacts thermal performance. That is, glass cores have poor heat transfer properties, which can be a detriment to the electronic package. In some high end applications, liquid cooling of the package substrate is used to improve the thermal performance. However, cavitation may occur over the glass core, which further reduces the thermal performance of the package substrate.

### BRIEF DESCRIPTION OF THE DRAWINGS

FIG. 1A is a cross-sectional illustration of a core with through glass vias (TGVs) and notches used to reduce cavitation on the core, in accordance with an embodiment.

FIG. 1B is a cross-sectional illustration of a core with TGVs and notches that have a flat bottom, in accordance with an embodiment.

FIG. 1C is a cross-sectional illustration of a core with TGVs and notches that have a depth greater than half the thickness of the core, in accordance with an embodiment.

FIG. 1D is a cross-sectional illustration of a core with TGVs and notches, where the width of the notches is smaller than a width of the TGVs, in accordance with an embodiment.

FIG. 2A is a cross-sectional illustration of a package substrate with a glass core that is wider than the buildup layers, and where notches are provided into the glass core outside of the buildup layers, in accordance with an embodiment.

FIG. 2B is a cross-sectional illustration of a package substrate with a glass core that is wider than the buildup layers, and where the buildup layers have a tapered sidewall, in accordance with an embodiment.

FIGS. 3A-3F are cross-sectional illustrations depicting a process for forming a package substrate with a glass core that includes notches, in accordance with an embodiment.

FIGS. 4A-4F are cross-sectional illustrations depicting a process for forming a package substrate with a glass core that includes notches, in accordance with an additional embodiment.

FIG. 5 is a cross-sectional illustration of an electronic system with a package substrate that includes a glass core with notches, in accordance with an embodiment.

FIG. 6 is a schematic of a computing device built in accordance with an embodiment.

### EMBODIMENTS OF THE PRESENT DISCLOSURE

Described herein are package substrates with glass cores that include exposed surfaces with angled baffles for cavitation protection, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, glass core package substrates provide mechanical and electrical benefits compared to organic core substrates. However, thermal performance of glass core packages can be a significant drawback. In advanced packaging architectures, a liquid cooling solution may be used in order to cool the package substrate. The exposed portions of the glass may undergo cavitation, which further reduces the heat transfer away from the glass core.

Accordingly, embodiments disclosed herein include glass cores that have one or more notches. The notches (sometimes referred to as baffles) reduce the presence of cavitation and improves heat transfer. Additionally, the notches increase the surface area of the core that is in contact with the thermal fluid. This also improves the heat transfer away from the package substrate. In some embodiments, the notches may be provided adjacent to edges of the core. The notches may be exposed. That is, the width of the buildup layers may be narrower than a width of the glass core, and the notches are outside of the buildup layers. In one particular instance, the notches have tapered sidewalls. This may result in a triangular shaped notch. In other embodiments, the notches may have flat bottoms. The notches may be narrower than the through glass vias (TGVs). Additionally, the notches may have a depth that is less than half the thickness of the core. Alternatively, the depth of the notches may be greater than half the thickness of the core. In such embodiments, the notches on opposite surfaces of the core may be offset from each other.

In an embodiment, glass cores with notches may be fabricated using various process flows. In one process flow, the notches are filled with a thermally decomposable polymer. After completion of the buildup layers, the polymer is decomposed, which results in material overlying the notches to lift off. In a second embodiment, the buildup layers are removed with a laser ablation process. In such embodiments, sidewalls of the buildup layers may be tapered.

In embodiments disclosed herein, glass cores are used for the package substrates. A glass core or a core that comprises glass may refer to a core substrate that is substantially all glass. That is, a core that comprises glass is distinct from a traditional organic core that may include glass fiber reinforcement. The glass material used in embodiments disclosed herein may be glass that is patternable with a laser assisted etching process. For example, the glass may include fused silica glass or a borosilicate glass. In such processes, the glass may be exposed by a laser. The laser results in a microstructure and/or phase of the glass being altered. The exposed portions of the glass may then be etch selective to the unexposed portions of the glass. For example, a wet etching process may be used in order to selectively etch the exposed portions of the glass relative to the unexposed portions of the glass.

In an embodiment, the glass cores described herein may have any suitable thickness. For example, the glass cores may have thicknesses between approximately 10 μm and approximately 1,000 μm. Though, thinner or thicker glass cores may also be used in some embodiments. As used herein, “approximately” may refer to a range of values within ten percent of the stated value. For example, approximately 10 μm may refer to a range of values between 9 μm and 11 μm. Depending on the thickness of the glass core, a single sided or double sided laser exposure may be necessary to pattern the glass using a laser assisted etching process. In the case of a double sided patterning operation, the TGVs may have an hourglass shaped profile. An hourglass shaped profile may refer to a structure that has a width at a midpoint of the structure that is narrower than the top and bottom of the structure.

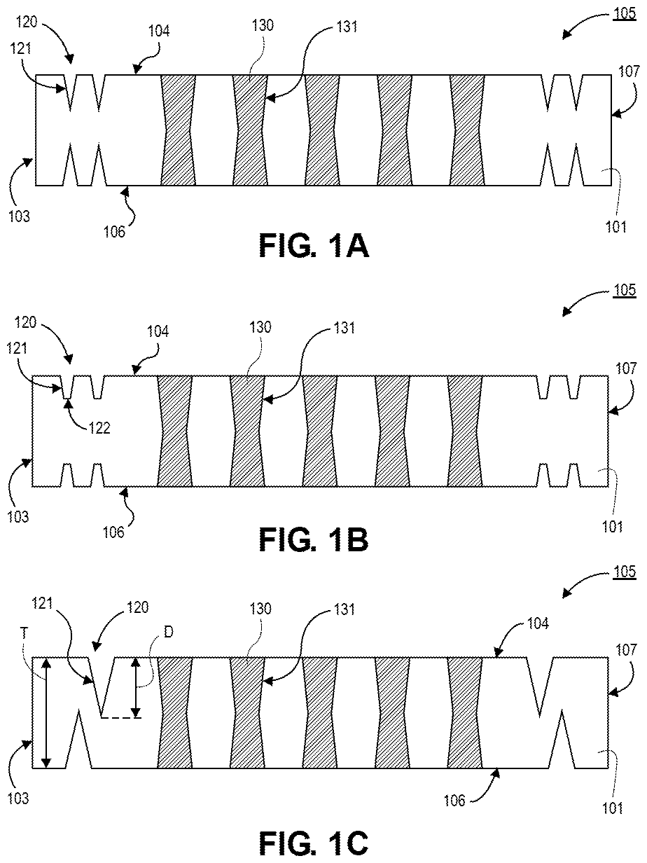

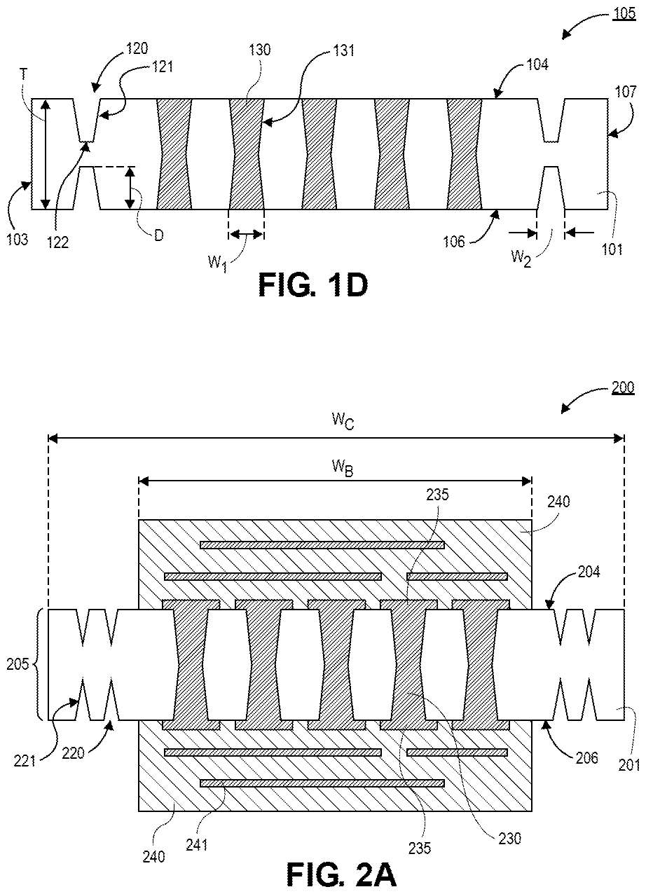

Referring now to FIG. 1A, a cross-sectional illustration of a core 105 is shown, in accordance with an embodiment. In an embodiment, the core 105 may comprise a substrate 101 that comprises glass. That is, the core 105 may be a glass core 105. The substrate 101 may comprise a glass material that is compatible with laser assisted patterning processes, such as those described in greater detail above. In an embodiment, the substrate 101 may include a first surface 104 and a second surface 106 opposite from the first surface 104. The substrate 101 may also include edges 103 and 107 that connect the first surface 104 to the second surface 106. In an embodiment, a thickness of the substrate 101 may be between approximately 10 μm and approximately 1,000 μm. Though thinner or thicker substrates 101 may be used in other embodiments.

In an embodiment, TGVs 130 may be formed through a thickness of the substrate 101. The TGVs 130 may have sloped sidewalls 131, typical of laser assisted patterning processes. In a particular embodiment, the TGVs 130 are formed with a dual sided patterning process, and the TGVs 130 include an hourglass shaped cross-section. In some instances, a narrowest portion of the TGVs 130 may be at a midpoint between the first surface 104 and the second surface 106.

In an embodiment, one or more notches 120 may be provided into the substrate 101. For example, notches 120 may be provided into the first surface 104 and the second surface 106 of the substrate 101. The notches 120 may be outside of the TGVs 130. That is, the notches 120 may be proximate to the edges 103 and 107 of the substrate 101. For example, the notches 120 may be within approximately 500 μm or less, within approximately 100 μm or less, or within approximately 50 μm or less of the edges 103 and 107. In the illustrated embodiment, four notches 120 are provided on each of the first surface 104 and the second surface 106. Though, it is to be appreciated that any number of notches 120 may be used, in accordance with various embodiments.

In an embodiment, the notches 120 are formed with a laser assisted patterning process. As such, the notches 120 may have tapered sidewalls 121. The tapered sidewalls 121 may meet at a point. In such embodiments, the notches 120 may be referred to as having a triangular shape or a triangular cross-section. In an embodiment, a depth of the notches 120 may be wider than a maximum width of the notches 120. In other embodiments, the depth of the notches 120 may be equal to, or wider than, a maximum width of the notches 120.

In an embodiment, the notches 120 may extend into and out of the plane of FIG. 1A. That is, the notches 120 may be trenches that surround the TGVs 130. For example, two trenches may surround a perimeter of the substrate 101. In other embodiments, the notches 120 may be referred to as holes, and a plurality of holes may be arranged around the perimeter of the substrate 101.

As described in greater detail above, the presence of the notches 120 will aid in improving the thermal performance of the core 105 when liquid cooling solutions are used to control a temperature of the package substrate. Particularly, the notches 120 are designed in order to minimize cavitation. Reducing or eliminating cavitation improves the thermal transfer from the core 105 to the cooling fluid. The notches 120 also increase the surface area in contact with the cooling fluid, which also improves heat transfer out of the core 105.

Referring now to FIG. 1B, a cross-sectional illustration of a core 105 is shown, in accordance with an additional embodiment. In an embodiment, the core 105 in FIG. 1B may be substantially similar to the core 105 described above in FIG. 1A, with the exception of the structure of the notches 120. That is, the core 105 in FIG. 1B may include TGVs 130 through a glass substrate 101. However, instead of having notches 120 that end in a point (e.g., for a triangular shaped cross-section), the notches 120 in FIG. 1B have flat bottom surfaces. That is, the bottom surfaces 122 may be substantially parallel to the first surface 104 and the second surface 106. In some embodiments, the flat bottom surfaces 122 may be provided as a result of the laser assisted patterning process. Due to the tapered sidewalls 121, the bottom surfaces 122 may be narrower than the opening of the notches 120 at the first surface 104 and the second surface 106.

Referring now to FIG. 1C, a cross-sectional illustration of a core 105 is shown, in accordance with an additional embodiment. In an embodiment, the core 105 in FIG. 1C may be substantially similar to the core 105 described above in FIG. 1A, with the exception of the structure of the notches 120. That is, the core 105 in FIG. 1C may include TGVs 130 through a glass substrate 101. However, instead of having notches 120 into the first surface 104 that are aligned with notches 120 into the second surface 106, the notches 120 into the first surface 104 may be offset from the notches 120 into the second surface 106. As such, the notches 120 may have a depth D that is greater than half the thickness T of the glass substrate 101. Increasing the depth of the notches 120 may further improve the thermal performance of the core 105 in some embodiments. In the illustrated embodiment, the notches 120 come to a point to provide a triangular cross-section. However, it is to be appreciated that the notches 120 may also have a flat bottom surface, similar to the embodiment shown in FIG. 1B.

Referring now to FIG. 1D, a cross-sectional illustration of a core 105 is shown, in accordance with an embodiment. In an embodiment, the core 105 in FIG. 1D may be substantially similar to the core 105 described above in FIG. 1A, with the exception of the structure of the notches 120. That is, the core 105 in FIG. 1D may include TGVs 130 through a glass substrate 101. However, instead of having notches 120 that end in a point, the notches 120 have flat bottom surfaces, similar to the embodiment described with respect to FIG. 1B. Additionally, the depth D of the notches 120 may be less than half the thickness T of the substrate 101. As such, the notches 120 into the first surface 104 may be aligned over the notches 120 into the second surface 106. Additionally, it is to be appreciated that a maximum width W₁ of the TGVs 130 may be greater than a maximum width W2 of the notches 120. However, in other embodiments, the notches 120 may have a maximum width W2 that is equal to or greater than a maximum width W₁ of the TGVs 130.

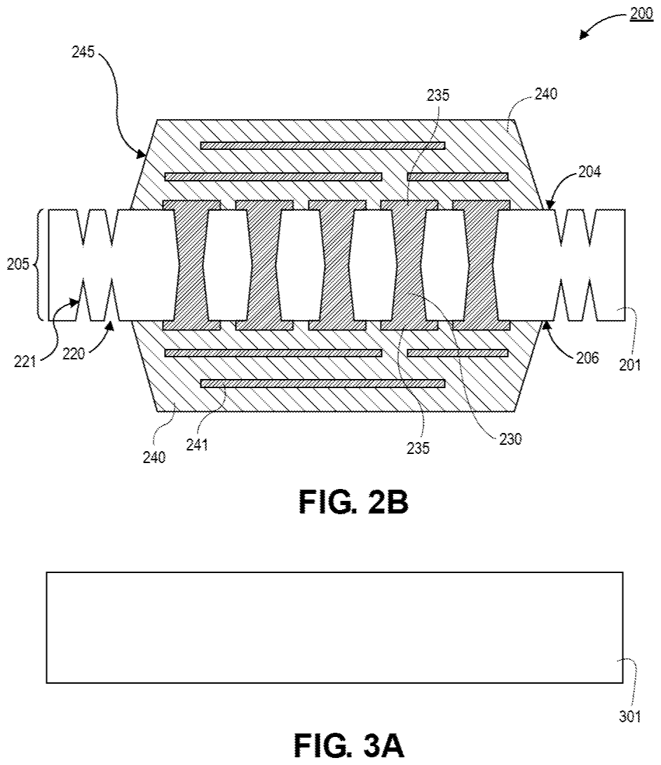

Referring now to FIG. 2A, a cross-sectional illustration of a package substrate 200 is shown, in accordance with an embodiment. In an embodiment, the package substrate 200 may comprise a core 205. The core 205 may include a glass substrate 201. TGVs 230 may pass through a thickness of the substrate 201. Pads 235 may be provided over the first surface 204 and the second surface 206 of the substrate 201. In an embodiment, buildup layers 240 may be provided over the first surface 204 and the second surface 206. The buildup layers 240 may include conductive routing (e.g., traces 241, pads, vias, etc.).

In an embodiment, a width W_{B} of the buildup layers 240 may be narrower than a width W_{C} of the core 205. As such, ends of the substrate 201 may be exposed. In an embodiment, one or more notches 220 may be provided into the first surface 204 and the second surface 206 of the substrate 201 outside of the buildup layers 240. That is, the notches 220 may surround a perimeter of the buildup layers 240 in some embodiments. In an embodiment, the notches 220 may include sloped sidewalls 221. The notches 220 may end at a point (to provide triangular shaped notches). In other embodiments, the notches 220 may have a flat bottom surface. More generally, the notches 220 may be similar to any of the notch architectures described in greater detail above with respect to FIGS. 1A-1D.

Referring now to FIG. 2B, a cross-sectional illustration of a package substrate 200 is shown, in accordance with another embodiment. In an embodiment, the package substrate 200 may be substantially similar to the package substrate 200 in FIG. 2A, with the exception of the buildup layers 240. That is, the package substrate 200 may include a core 205 with a glass substrate 201 and TGVs 230. Notches 220 may be provided into the substrate 201 around an outer perimeter of the buildup layers 240. However, instead of having a buildup layer 240 with substantially vertical sidewalls, embodiments include buildup layers 240 with sidewalls 245 that are tapered. The tapered sidewalls 245 may be the result of a laser ablation process used to expose the notches 220. As such, a top surface of the buildup layers 240 may be narrower than a bottom surface of the buildup layers 240 that interfaces with the first surface 204 or the second surface 206 of the substrate 201. While a particular notch 220 architecture is shown in FIG. 2B, it is to be appreciated that the notches 220 may have any architecture described herein. For example, any of the notch 120 architectures in FIGS. 1A-1D may be used for the notches 220 in FIG. 2B.

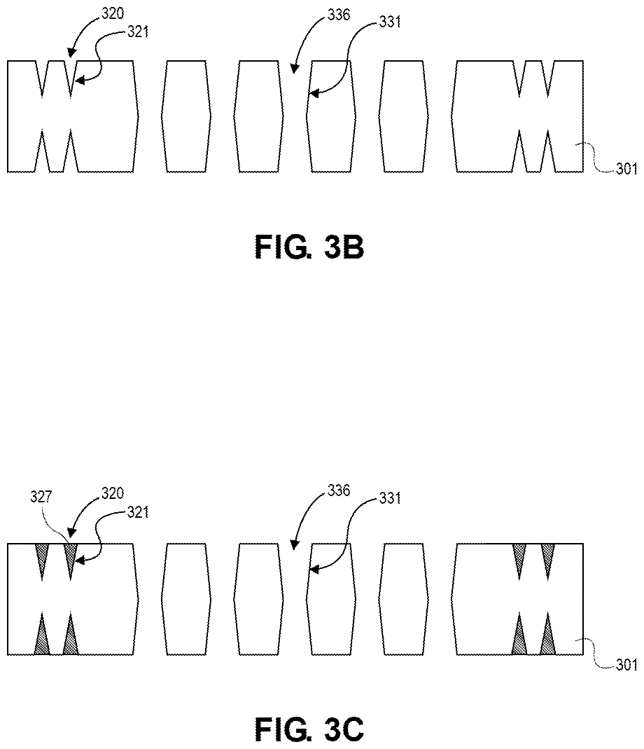

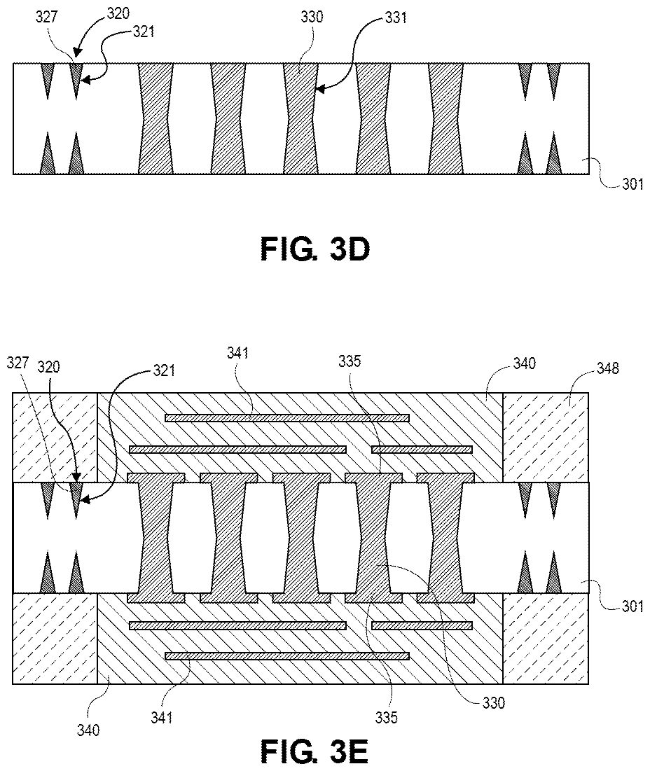

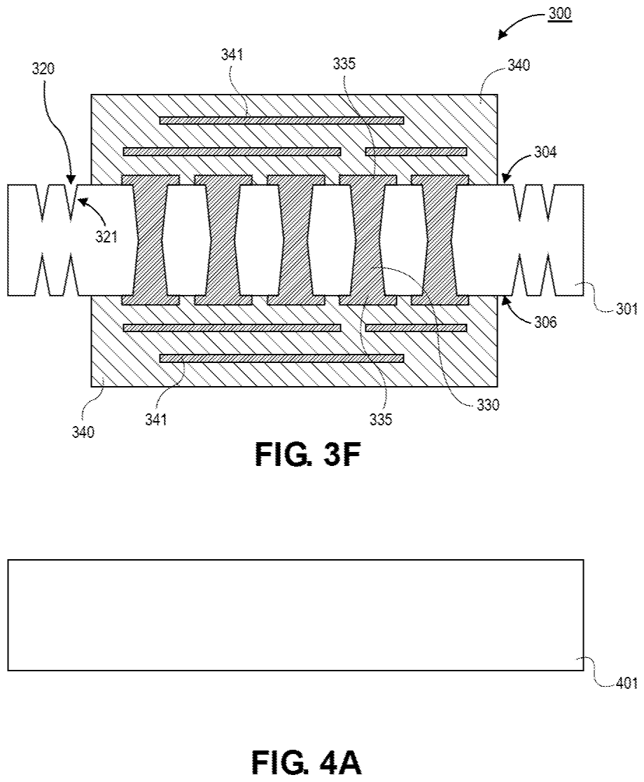

Referring now to FIGS. 3A-3F a series of cross-sectional illustrations depicting a process for forming a package substrate 300 is shown, in accordance with an embodiment. In an embodiment, the package substrate 300 may be similar to the package substrate 200 shown in FIG. 2A. That is, sidewalls of the buildup layers 340 may be substantially vertical. Such an embodiment may be manufactured using a decomposable polymer solution.

Referring now to FIG. 3A, a cross-sectional illustration of a substrate 301 is shown, in accordance with an embodiment. In an embodiment, the substrate 301 may comprise glass. That is, the substrate 301 may be a glass substrate 301. The substrate 301 may have any suitable thickness for a glass core architecture of a package substrate. For example, the substrate 301 may have a thickness between approximately 10 μm and approximately 1,000 μm. Though, thinner or thicker substrates 301 may also be used in some embodiments. In an embodiment, the substrate 301 may comprise a glass formulation that is compatible with laser assisted patterning processes, such as those described in greater detail above.

Referring now to FIG. 3B, a cross-sectional illustration of the substrate 301 after the substrate 301 has been patterned is shown, in accordance with an embodiment. In an embodiment, the substrate 301 may be patterned with a laser assisted patterning process. The patterning may include forming a plurality of via openings 336. The via openings 336 may include tapered sidewalls 331. For example, the via openings 336 may have hourglass shaped cross-sections in some embodiments.

In an embodiment, the patterning may also result in the formation of notches 320. The notches 320 may be formed into one or both of the top surface and the bottom surface of the substrate 301. The notches 320 may also have tapered sidewalls 321. The sidewalls 321 may meet at a point in order to provide notches 320 with a triangular shaped cross-section. In other embodiments, notches with flat bottom surfaces may be formed with the patterning process. More generally, notches 320 with any architecture described herein may be patterned into the substrate 301.

Referring now to FIG. 3C, a cross-sectional illustration of the substrate 301 after plugs 327 are formed into the notches 320 is shown, in accordance with an embodiment. In an embodiment, the plugs 327 may be a polymer material. More particularly, the plugs 327 may be a polymer that is thermally decomposable at temperatures below the maximum operating temperature of the package substrate. As such, after the buildup layers are fabricated over the substrate 301, the temperature of the package substrate is raised so that the plugs 327 thermally decompose and lift off the overlying material, as will be described in greater detail below. Any suitable polymer with a decomposition temperature at or below 500° C., at or below 200° C., or at or below 150° C. may be used for the plugs 327.

The plugs 327 may be deposited with a lamination process, a deposition process, or the like. Additionally, while the notches 320 are shown as being formed substantially in parallel with the via openings 336, the notches 320 may be formed before the via openings 336. This may allow for the plugs 327 to be formed in the notches 320 before the via openings 336 are formed. In such embodiments, masking layers or the like may not be needed over the via openings 336 in order to form the plugs 327.

Referring now to FIG. 3D, a cross-sectional illustration of the substrate 301 after the TGVs 330 are formed is shown, in accordance with an embodiment. In an embodiment, the TGVs 330 may be formed with any suitable plating process (e.g., electroplating, electroless plating, or the like). In some embodiments, a seed layer may first be deposited in order to plate the TGVs 330. In such embodiments, the seed layer may subsequently be etched to electrically isolate the TGVs 330 from each other. In some embodiments, pads (not shown in FIG. 3D) may be patterned before etching the seed layer. As shown, the TGVs 330 may conform to the shape of the via openings 336. That is, the TGVs 330 may have an hourglass shaped cross-section in some embodiments.

Referring now to FIG. 3E, a cross-sectional illustration of the substrate 301 after buildup layers 340 are formed over and under the substrate 301. The buildup layers 340 may comprise conductive features (e.g., traces 341, pads, vias, etc.). The conductive features may be coupled to pads 335 that are formed over and under the TGVs 330. In an embodiment, the buildup layers 340 may also comprise voided regions 348. The voided regions 348 may be provided over the notches 320. The voided regions 348 may be portions of the buildup layers 340 that do not include conductive features. In some embodiments, the voided regions 348 may be the same material as the buildup layers 340. In other embodiments, the voided regions 348 may include a material different than the buildup layers 340. The voided regions 348 are configured so that they can be lifted off when the plugs 327 are thermally decomposed.

Referring now to FIG. 3F, a cross-sectional illustration of the package substrate 300 after the plugs 327 are thermally decomposed is shown, in accordance with an embodiment. As shown, thermal decomposition of the plugs 327 also results in the lift off of the voided regions 348. As such, the buildup layers 340 may have substantially vertical sidewalls that are within a perimeter of the notches 320. That is, a first surface 304 and a second surface 306 of the substrate 301 may be exposed. The thermal decomposition temperature may be a temperature compatible with the buildup layers 340. That is, the thermal decomposition temperature may not negatively impact the buildup layers 340.

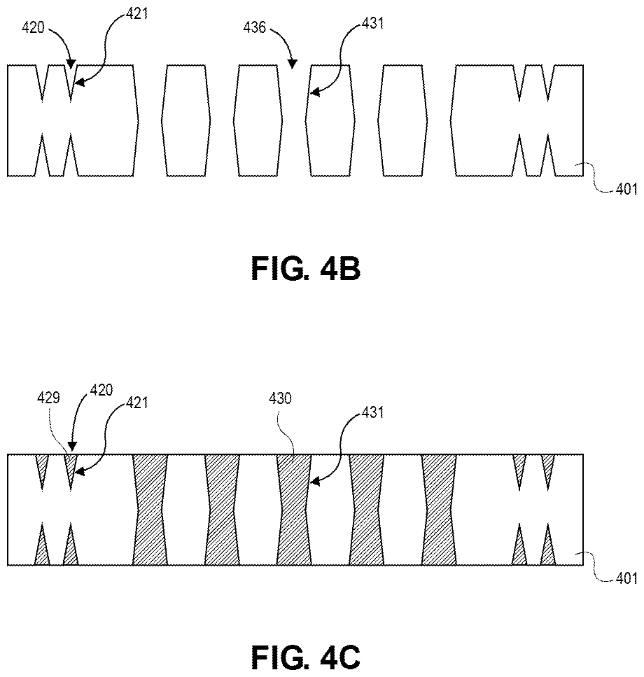

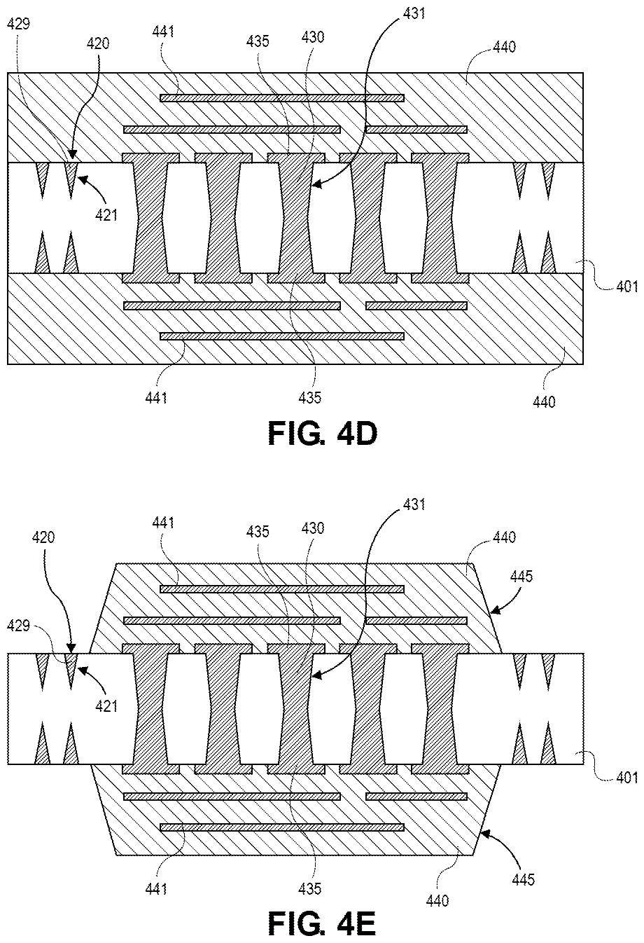

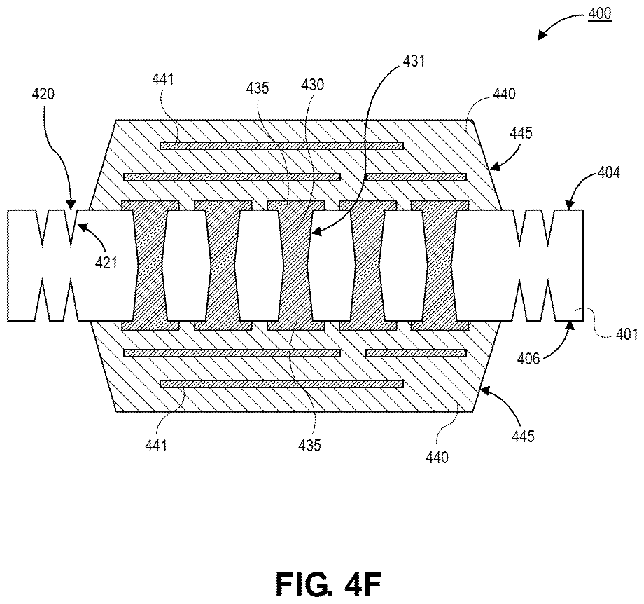

Referring now to FIGS. 4A-4F a series of cross-sectional illustrations depicting a process for forming a package substrate 400 is shown, in accordance with an embodiment. In an embodiment, the package substrate 400 may be similar to the package substrate 200 shown in FIG. 2B. That is, sidewalls of the buildup layers 440 may be sloped. Such an embodiment may be manufactured using a laser ablation process to expose the notches.

Referring now to FIG. 4A, a cross-sectional illustration of a substrate 401 is shown, in accordance with an embodiment. In an embodiment, the substrate 401 may comprise glass. That is, the substrate 401 may be a glass substrate 401. The substrate 401 may have any suitable thickness for a glass core architecture of a package substrate. For example, the substrate 401 may have a thickness between approximately 10 μm and approximately 1,000 μm. Though, thinner or thicker substrates 401 may also be used in some embodiments. In an embodiment, the substrate 401 may comprise a glass formulation that is compatible with laser assisted patterning processes, such as those described in greater detail above.

Referring now to FIG. 4B, a cross-sectional illustration of the substrate 401 after the substrate 401 has been patterned is shown, in accordance with an embodiment. In an embodiment, the substrate 401 may be patterned with a laser assisted patterning process. The patterning may include forming a plurality of via openings 436. The via openings 436 may include tapered sidewalls 431. For example, the via openings 436 may have hourglass shaped cross-sections in some embodiments.

In an embodiment, the patterning may also result in the formation of notches 420. The notches 420 may be formed into one or both of the top surface and the bottom surface of the substrate 401. The notches 420 may also have tapered sidewalls 421. The sidewalls 421 may meet at a point in order to provide notches 420 with a triangular shaped cross-section. In other embodiments, notches with flat bottom surfaces may be formed with the patterning process. More generally, notches 420 with any architecture described herein may be patterned into the substrate 401.

Referring now to FIG. 4C, a cross-sectional illustration of the substrate 401 after TGVs 430 are plated is shown, in accordance with an embodiment. Additionally, plugs 429 may be plated in the notches 420. In an embodiment, the plating may be electroless plating, electrolytic plating, or the like. In some embodiments, a seed layer may be deposited to assist in the plating process. The seed layer may be removed after pads (not shown in FIG. 4C) are formed.

Referring now to FIG. 4D, a cross-sectional illustration of the substrate 401 after buildup layers 440 are formed over the substrate 401 is shown, in accordance with an embodiment. In an embodiment, the buildup layers 440 may include conductive features (e.g. traces 441, pads, vias, etc.). The buildup layers 440 may also include voided regions over the notches 420. The voided regions may be regions of the buildup layers 440 that are free from conductive features. As such, the outer portions of the buildup layers 440 may be removed with a laser ablation process.

Referring now to FIG. 4E, a cross-sectional illustration of the substrate 401 after the buildup layers 440 are patterned is shown, in accordance with an embodiment. For example, a laser ablation process may be used to remove portions of the buildup layers 440 over the notches 420. The use of a laser ablation process may result in the sidewalls 445 of the buildup layers 440 being tapered. For example, a first surface of the buildup layers 440 may be narrower than a second surface of the buildup layers 440 that interface with the substrate 401.

Referring now to FIG. 4F, a cross-sectional illustration of a package substrate 400 after the notches 420 are cleared is shown, in accordance with an embodiment. In an embodiment, the plugs 429 may be removed with an etching process, such as a wet etching process. In some embodiments, laser ablation may also be used to remove the plugs 429. As shown, the package substrate 400 includes buildup layers 440 that expose the notches 420 formed into the first surface 404 and the second surface 406 of the substrate 401.

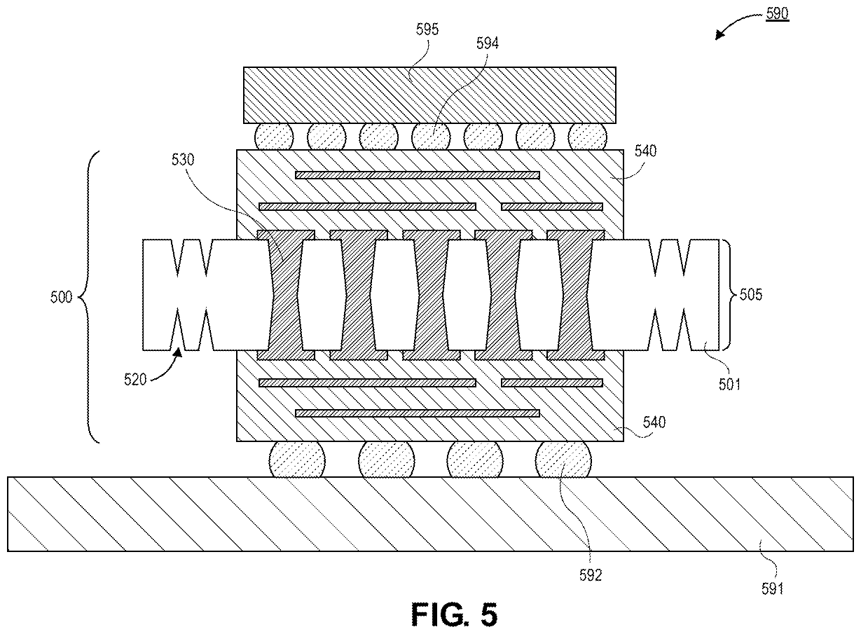

Referring now to FIG. 5, a cross-sectional illustration of an electronic system 590 is shown, in accordance with an embodiment. In an embodiment, the electronic system 590 may comprise a board 591, such as a printed circuit board (PCB) or the like. A package substrate 500 may be coupled to the board 591 by interconnects 592. While shown as solder interconnects 592, it is to be appreciated that any suitable architecture may be used for the interconnects 592.

In an embodiment, the package substrate 500 may comprise a core 505. The core 505 may include a glass substrate 501. TGVs 530 may pass through the substrate 501. Additionally, one or more notches 520 may be formed into the top and/or bottom surface of the substrate 501. The notches 520 shown in FIG. 5 include triangle shaped cross-sections. Though, it is to be appreciated that any notch architecture described herein may be used in the package substrate 500. In an embodiment, the package substrate 500 may also include buildup layers 540 over the surfaces of the substrate 501. The sidewalls of the buildup layers 540 may be substantially vertical or sloped. The width of the buildup layers 540 is smaller than a width of the substrate 501. This allows for the notches 520 to be exposed.

In an embodiment, one or more dies 595 may be coupled to the package substrate 500. For example, die 595 is coupled to the package substrate 500 by interconnects 594. While solder interconnects 594 are shown in FIG. 5, it is to be appreciated that any first level interconnect (FLI) architecture may be used in accordance with various embodiments. The one or more dies 595 may comprise compute dies 595, memory dies 595, and/or any other type of die 595.

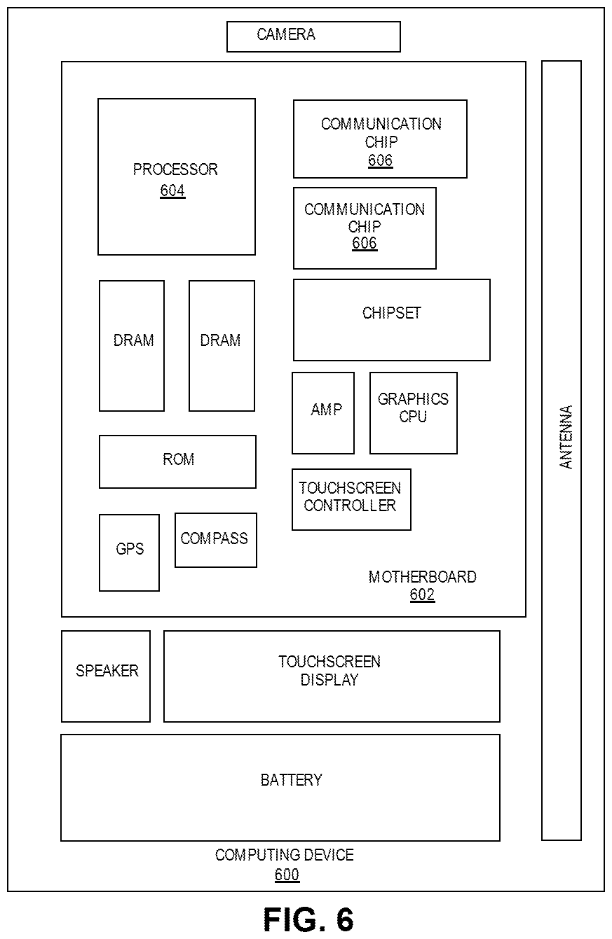

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor may be part of an electronic system that includes a package substrate with a core that includes notches for thermal performance improvement, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip may be part of an electronic system that includes a package substrate with a core that includes notches for thermal performance improvement, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a core, comprising: a substrate with a first surface and a second surface opposite from the first surface, wherein the substrate comprises glass; through glass vias (TGVs) through the substrate; and notches into the first surface and the second surface of the substrate.

Example 2: the core of Example 1, wherein the notches are provided proximate to edges of the substrate.

Example 3: the core of Example 2, wherein the notches comprise first notches into the first surface of the substrate, wherein the first notches are adjacent to a first edge of the substrate and a second edge of the substrate, and wherein the notches further comprise second notches into the second surface of the substrate, wherein the second notches are adjacent to the first edge of the substrate and the second edge of the substrate.

Example 4: the core of Examples 1-3, wherein the notches are triangular notches into the substrate.

Example 5: the core of Examples 1-4, wherein the notches have a flat bottom surface.

Example 6: the core of Examples 1-5, wherein the notches comprise four two or more notches.

Example 7: the core of Examples 1-6, wherein the notches comprise four or more notches.

Example 8: the core of Examples 1-7, wherein the TGVs have hourglass shaped cross-sections.

Example 9: the core of Examples 1-8, wherein a width of the notches is smaller than a width of the TGVs.

Example 10: the core of Examples 1-9, wherein the glass comprises fused silica glass or a borosilicate glass.

Example 11: a package substrate, comprising: a core with a first surface and a second surface opposite from the first surface, wherein the core comprises glass; through glass vias (TGVs) through the core; buildup layers over the first surface and the second surface of the core, wherein a width of the buildup layers is less than a width of the core; and notches into the first surface and/or the second surface of the core, wherein the notches are outside of the buildup layers.

Example 12: the package substrate of Example 11, wherein the notches comprise two or more notches.

Example 13: the package substrate of Example 11 or Example 12, wherein the notches have a depth that is less than half a thickness of the core.

Example 14: the package substrate of Examples 11-13, wherein the notches are triangular.

Example 15: the package substrate of Examples 11-14, wherein the notches comprise flat bottom surfaces.

Example 16: the package substrate of Examples 11-15, wherein edges of the buildup layers are substantially vertical.

Example 17: the package substrate of Examples 11-16, wherein edges of the buildup layers are tapered.

Example 18: the package substrate of Example 17, wherein first surfaces of the buildup layers on the core are wider than second surfaces of the buildup layers away from the core.

Example 19: the package substrate of Examples 11-18, wherein a width of the notches is smaller than a width of the TGVs.

Example 20: the package substrate of Examples 11-19, wherein the TGVs have hourglass shaped cross-sections.

Example 21: the package substrate of Examples 11-20, wherein first notches are into the first surface of the core, wherein the first notches are to the left of the buildup layer and to the right of the buildup layer, and wherein second notches are into the second surface of the core, wherein the second notches are to the left of the buildup layer and to the right of the buildup layer.

Example 22: the package substrate of Example 21, wherein there are two or more first notches, and wherein there are two or more second notches.

Example 23: an electronic system, comprising: a board; a package substrate coupled to the board, wherein the package substrate comprises: a core, wherein the core comprises glass; through glass vias (TGVs) through the core; notches into a top surface and/or a bottom surface of the core, wherein the notches have sloped sidewalls; and buildup layers over the top surface and the bottom surface of the core, wherein the notches are adjacent to sidewalls of the buildup layers; and a die coupled to the package substrate.

Example 24: the electronic system of Example 23, wherein the sidewalls of the buildup layers are tapered.

Example 25: the electronic package of Example 23 or Example 24, wherein the notches have flat bottom surfaces.

What is claimed is:

1. A core, comprising:
a substrate with a first surface and a second surface opposite from the first surface, wherein the substrate comprises glass;
through glass vias (TGVs) through the substrate; and
notches into the first surface and the second surface of the substrate.

2. The core of claim 1, wherein the notches are provided proximate to edges of the substrate.

3. The core of claim 2, wherein the notches comprise first notches into the first surface of the substrate, wherein the first notches are adjacent to a first edge of the substrate and a second edge of the substrate, and wherein the notches further comprise second notches into the second surface of the substrate, wherein the second notches are adjacent to the first edge of the substrate and the second edge of the substrate.

4. The core of claim 1, wherein the notches are triangular notches into the substrate.

5. The core of claim 1, wherein the notches have a flat bottom surface.

6. The core of claim 1, wherein the notches comprise four two or more notches.

7. The core of claim 1, wherein the notches comprise four or more notches.

8. The core of claim 1, wherein the TGVs have hourglass shaped cross-sections.

9. The core of claim 1, wherein a width of the notches is smaller than a width of the TGVs.

10. The core of claim 1, wherein the glass comprises fused silica glass or a borosilicate glass.

11. A package substrate, comprising:
a core with a first surface and a second surface opposite from the first surface, wherein the core comprises glass;
through glass vias (TGVs) through the core;
buildup layers over the first surface and the second surface of the core, wherein a width of the buildup layers is less than a width of the core; and
notches into the first surface and/or the second surface of the core, wherein the notches are outside of the buildup layers.

12. The package substrate of claim 11, wherein the notches comprise two or more notches.

13. The package substrate of claim 11, wherein the notches have a depth that is less than half a thickness of the core.

14. The package substrate of claim 11, wherein the notches are triangular.

15. The package substrate of claim 11, wherein the notches comprise flat bottom surfaces.

16. The package substrate of claim 11, wherein edges of the buildup layers are substantially vertical.

17. The package substrate of claim 11, wherein edges of the buildup layers are tapered.

18. The package substrate of claim 17, wherein first surfaces of the buildup layers on the core are wider than second surfaces of the buildup layers away from the core.

19. The package substrate of claim 11, wherein a width of the notches is smaller than a width of the TGVs.

20. The package substrate of claim 11, wherein the TGVs have hourglass shaped cross-sections.

21. The package substrate of claim 11, wherein first notches are into the first surface of the core, wherein the first notches are to the left of the buildup layer and to the right of the buildup layer, and wherein second notches are into the second surface of the core, wherein the second notches are to the left of the buildup layer and to the right of the buildup layer.

22. The package substrate of claim 21, wherein there are two or more first notches, and wherein there are two or more second notches.

23. An electronic system, comprising:
a board;
a package substrate coupled to the board, wherein the package substrate comprises:
a core, wherein the core comprises glass;
through glass vias (TGVs) through the core;
notches into a top surface and/or a bottom surface of the core, wherein the notches have sloped sidewalls; and
buildup layers over the top surface and the bottom surface of the core, wherein the notches are adjacent to sidewalls of the buildup layers; and
a die coupled to the package substrate.

24. The electronic system of claim 23, wherein the sidewalls of the buildup layers are tapered.

25. The electronic package of claim 23, wherein the notches have flat bottom surfaces.
